(19) United States
(12) Patent Application Publication
(10) Pub. No.: US 2026/0282543 A1
(43) Pub. Date: Sep. 17, 2026

(54) SELF-LUMINOUS DISPLAY DEVICE AND METHOD FOR MANUFACTURING SELF-LUMINOUS DISPLAY DEVICE

(71) Applicant: Sharp Display Technology Corporation, Kameyama City, Mie (JP)

(72) Inventors: Takeshi HARA, Kameyama City (JP); Kenichi KITOH, Kameyama City (JP)

(21) Appl. No.: 19/168,979

(22) PCT Filed: Mar. 28, 2023
(86) PCT No.: PCT/JP2023/012359

§ 371 Date: Sep. 25, 2025

(51) Int. Cl. H10D 86/40; H10D 86/01; H10D 86/60; H10H 29/32

(52) U.S. Cl. CPC H10D 86/423; H10D 86/0221; H10D 86/0231; H10D 86/60; H10H 29/32

(57) ABSTRACT

A self-luminous display device according to the disclosure includes a first pixel circuit including a first transistor including a first channel layer including an oxide semiconductor, and a second pixel circuit with the same circuit configuration as the first pixel circuit and including a second transistor corresponding to the first transistor and including a second channel layer including an oxide semiconductor, in which a gate length of the second transistor is longer than a gate length of the first transistor, and the oxide semiconductor included in the second transistor is more reduced than the oxide semiconductor included in the first transistor.

### TECHNICAL FIELD

The disclosure relates to a self-luminous display device and a method for manufacturing a self-luminous display device.

### BACKGROUND ART

PTL 1 discloses that a film thickness of a gate insulating film affects the threshold values of transistors.

### CITATION LIST

### Patent Literature

PTL 1: JP 2015-060996 A (published on Mar. 30, 2015)

### SUMMARY

### Technical Problem

The threshold values of transistors are affected by a gate length and a carrier concentration of the channel layer. For this reason, the actual threshold values of the transistors vary, causing the display quality to be easily degraded.

### Solution to Problem

A self-luminous display device according to an aspect of the disclosure includes a first pixel circuit including a first transistor including a first channel layer including an oxide semiconductor, and a second pixel circuit with the same circuit configuration as the first pixel circuit, the second pixel circuit including a second transistor corresponding to the first transistor, the second transistor including a second channel layer including an oxide semiconductor, in which a gate length of the second transistor is longer than a gate length of the first transistor, and the oxide semiconductor included in the second channel layer is more reduced than the oxide semiconductor included in the first channel layer.

A method for manufacturing a self-luminous display device according to an aspect of the disclosure includes forming a channel layer including an oxide semiconductor of a transistor, forming a first insulating layer in contact with the channel layer, etching the first insulating layer or introducing oxygen into the first insulating layer by using a first plasma to form a hole penetrating the first insulating layer, annealing the channel layer and the first insulating layer after using the first plasma, forming a conductive layer serving as a material of a gate electrode of the transistor, and etching the conductive layer with a second plasma to form the gate electrode of the transistor from the conductive layer.

### Advantageous Effects of Disclosure

According to an aspect of the disclosure, the display quality of the display device can be improved.

### BRIEF DESCRIPTION OF DRAWINGS

FIG. 1 is a plan view illustrating a configuration example of a self-luminous display device according to an embodiment of the disclosure.

FIG. 2 is a transparent plan view illustrating a configuration example of a first transistor and a second transistor illustrated in FIG. 1.

FIG. 3 is a cross-sectional view illustrating a configuration example of the first transistor and the second transistor illustrated in FIG. 1.

FIG. 4 is a cross-sectional view illustrating a configuration example of the first transistor and the second transistor illustrated in FIG. 1.

FIG. 5 illustrates cross-sectional views of an example of a method for manufacturing the self-luminous display device according to an embodiment of the disclosure.

FIG. 6 is a plan view illustrating an example of an intensity distribution of plasma illustrated in FIG. 5.

FIG. 7 is a cross-sectional view illustrating a configuration example of a self-luminous display device according to an embodiment of the disclosure.

FIG. 8 illustrates cross-sectional views of an example of the method for manufacturing the self-luminous display device according to an embodiment of the disclosure.

FIG. 9 is a cross-sectional view illustrating a configuration example of the self-luminous display device according to an embodiment of the disclosure.

FIG. 10 is a cross-sectional view illustrating an example of the method for manufacturing the self-luminous display device according to an embodiment of the disclosure.

FIG. 11 illustrates cross-sectional views of the example of the method for manufacturing the self-luminous display device according to an embodiment of the disclosure.

### DESCRIPTION OF EMBODIMENTS

### First Embodiment

### Configuration

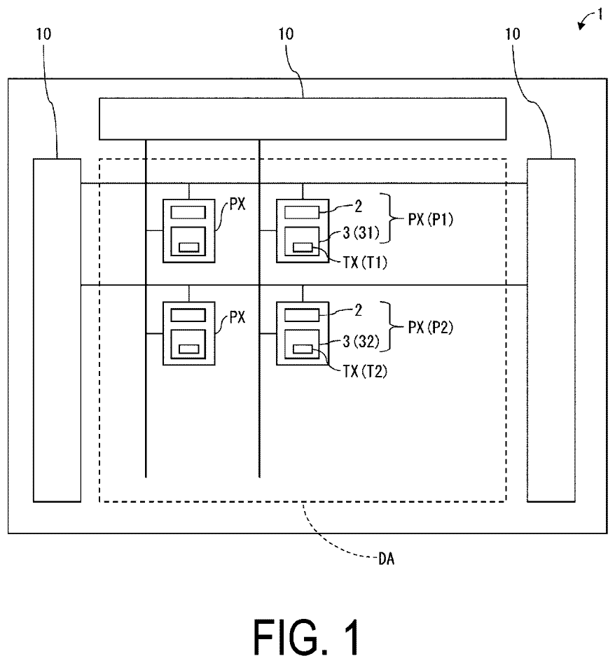

FIG. 1 is a plan view illustrating a configuration example of a self-luminous display device according to an embodiment of the disclosure. A self-luminous display device 1 according to the disclosure includes a display portion DA including a plurality of pixels PX, and a drive circuit 10 that drives the display portion DA as illustrated in FIG. 1. Each of the plurality of pixels PX includes a light-emitting element 2 and a pixel circuit 3 that controls a current or a voltage applied to the light-emitting element 2. Each pixel circuit 3 includes a transistor TX, and each transistor TX has a channel layer including an oxide semiconductor.

The self-luminous display device 1 includes a first pixel circuit 31 including a first transistor T1 including a first channel layer including an oxide semiconductor, and a second pixel circuit 32 having the same circuit configuration as the first pixel circuit 31 and including a second transistor T2 corresponding to the first transistor T1 and including a second channel layer including an oxide semiconductor. More specifically, the second pixel circuit 32 has identical arrangement and connection relationship of the circuit elements to those of the first pixel circuit 31 in design, and has identical characteristics of the corresponding circuit elements. The characteristics of the circuit elements are, for example, a threshold value of a transistor, a capacitance value of a capacitance element, and the like. The threshold value of a gate voltage of a transistor using an oxide semiconductor depends on a gate length of the transistor and the degree of reduction of the oxide semiconductor in the transistor as is well known. For this reason, the first transistor T1 and the second transistor T2 are designed to have the same threshold value, the same gate lengths, and the same degrees of reduction. The first transistor T1 and the second transistor T2 are drive transistors. The first transistor T1 and the second transistor T2 will be focused on below.

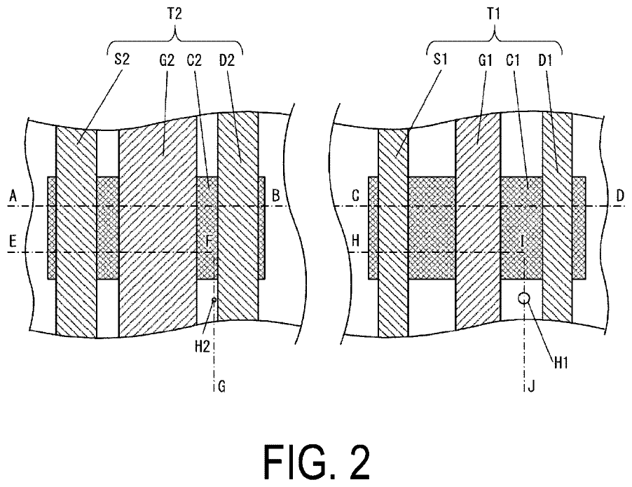

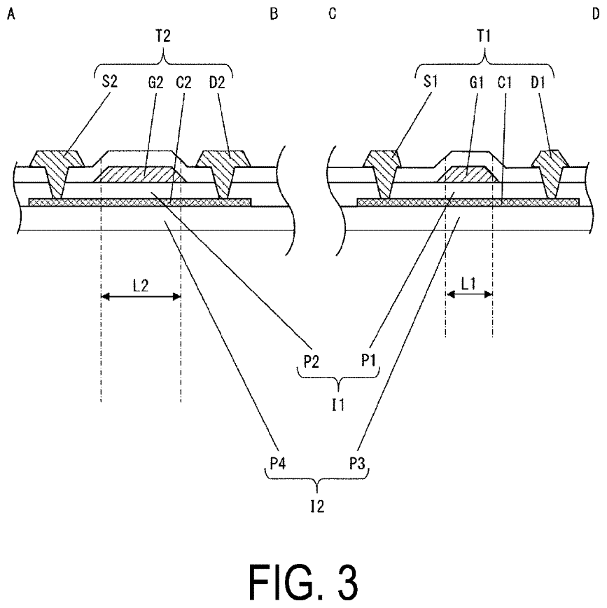

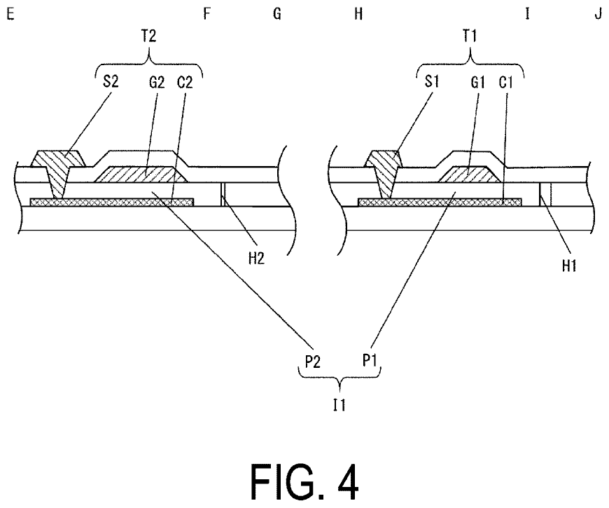

FIGS. 2, 3, and 4 are a transparent plan view, a cross-sectional view, and a cross-sectional view, respectively, illustrating configuration examples of the first transistor and the second transistor illustrated in FIG. 1. FIG. 3 shows the cross-section cut along the line ABCD of FIG. 2, and FIG. 4 shows the cross-section cut along the lines EFGHIJ of FIG. 2. The first transistor T1 includes a gate electrode G1, a source electrode S1, a drain electrode D1, and a first channel layer C1 including an oxide semiconductor as illustrated in FIGS. 2 to 4. The second transistor T2 includes a gate electrode G2, a source electrode S2, a drain electrode D2, and a second channel layer C2 including an oxide semiconductor.

An actual gate length L2 of the second transistor T2 is longer than the actual gate length L1 of the first transistor T1, and the actual oxide semiconductor included in the second channel layer C2 has been reduced more than the actual oxide semiconductor included in the first channel layer C1. These actual differences are attributable to the manufacturing process. Hereinafter, unless otherwise specified as “designed” or “ideal”, actual values and differences will be described.

According to the above configuration, the difference between the gate lengths L1 and L2 acts to make the threshold value of the second transistor T2 greater than the threshold value of the first transistor T1. On the other hand, the difference in the degree of reduction of the oxide semiconductors acts to make the threshold value of the second transistor T2 smaller than the threshold value of the first transistor T1. As a result of these effects (at least partially) canceling each other, the difference in the threshold values of the first transistor T1 and the second transistor T2 can be reduced.

As a comparative example, transistors having different gate lengths and the same degree of reduction of an oxide semiconductor are conceivable. In this case, a difference in gate length is directly linked to a difference in threshold value, and the difference in threshold value is large. In a plurality of pixel circuits of the self-luminous display device, such a large difference in threshold value causes uneven luminance and a degraded display quality. Although adjustment is usually performed before shipment to eliminate visible uneven luminance (referred to as “de-unevenness processing”) in commercial practices, uneven luminance to a degree that is difficult to correct may remain. In addition, the difference in threshold values leads to a difference in aging change, causing uneven luminance after the aging change and resulting in deteriorating display quality.

According to the configuration of the disclosure, the difference in threshold values is small, and thus, uneven luminance of the pixel before the de-unevenness processing is small. Therefore, the display quality of the self-luminous display device 1 can be improved, and in particular, the display quality after the aging change can be improved.

The first transistor T1 and the second transistor T2 are thin film transistors. The oxide semiconductor included in the first channel layer C1 and the oxide semiconductor included in the second channel layer C2 may be made of the same material. The oxide semiconductor may include, for example, copper oxide, silver oxide, zinc oxide, gallium oxide, tin oxide, indium oxide, indium gallium zinc oxide, indium tin oxide, indium zinc oxide, titanium oxide, indium titanium oxide, or indium titanium zinc oxide. The gate electrode G1 and the gate electrode G2 are formed in the same layer, and the first channel layer C1 and the second channel layer C2 are formed in the same layer. The source electrodes S1 and S2 and the drain electrodes D1 and D2 may be formed in the same layer.

The self-luminous display device 1 includes a first insulating layer Il having a first portion P1 in contact with an upper face of the first channel layer C1 and a second portion P2 in contact with an upper face of the second channel layer C2. The density of hydrogen contained in the second portion P2 is higher than the density of hydrogen contained in the first portion P1. Furthermore, the diameter of a second hole H2 penetrating the vicinity of the second portion P2 is smaller than the diameter of a first hole H1 penetrating the vicinity of the first portion P1. The first hole H1 is a through-hole for dehydrogenation of the first portion P1, and the second hole H2 is a through-hole for dehydrogenation of the second portion P2. The diameter of the second hole H2 may be 0, in other words, there may be no dehydrogenation hole in the vicinity of the second portion P2. The first insulating layer I1 may be an inorganic insulating layer, and may contain, for example, silicon nitride (SiN), silicon oxide (SiO), or silicon oxynitride (SiNO).

### Manufacturing Method

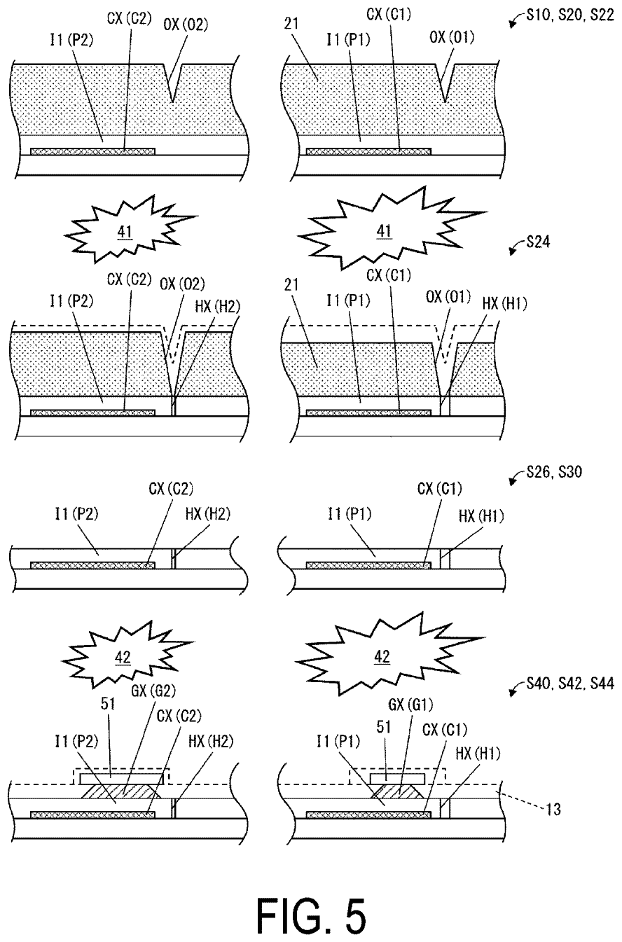

FIG. 5 illustrates cross-sectional views of an example of a method for manufacturing a self-luminous display device according to an embodiment of the disclosure. First, a first channel layer CX containing an oxide semiconductor of a transistor is formed (step S10), and the first insulating layer I1 in contact with the channel layer CX is formed (step S20) as illustrated in FIG. 5. The channel layer CX includes the first channel layer C1 and the second channel layer C2. The first insulating layer I1 is formed over the channel layer CX. The first insulating layer I1 contains hydrogen at the time of formation.

Subsequently, a photoresist layer 21 having openings OX is formed on the first insulating layer I1 (step S22). The openings OX include a first opening O1 overlapping with the formation-planned position of the first hole H1 and a second opening O2 overlapping with the formation-planned position of the second hole H2. Ideally, the depth and diameter of the second opening O2 are identical to the depth and diameter of the first opening O1. It is advantageous for the openings OX not to penetrate. The photoresist layer 21 having the openings OX that are not penetrating may be realized by using a half-tone mask or a gray-tone mask.

Then, the photoresist layer 21 and the first insulating layer Il are etched with a first plasma 41 to form holes HX penetrating the first insulating layer I1 (step S24), and the photoresist layer 21 is removed (step S26). The openings OX overlap the holes HX in a plan view. The holes HX penetrating the first insulating layer Il include a first hole H1 and a second hole H2. In step S24, the stronger the first plasma 41 is, the larger the diameters of the openings OX and the holes HX are. Specifically, the diameter of the first hole H1 formed in the region where the intensity of the first plasma 41 is strong is larger than the diameter of the second hole H2 formed in the region where the intensity of the first plasma 41 is weak.

When the openings OX do not penetrate in step S22, the photoresist layer 21 is etched with the first plasma 41 in step S24 so that the openings OX penetrate the photoresist layer 21, and further the first insulating layer I1 is etched to form the holes HX. Therefore, it is easy to create a difference in diameters between the first hole H1 and the second hole H2. In particular, the diameter of the second hole H2 can be set to 0, in other words, no dehydrogenation hole can be formed in the region where the intensity of the first plasma 41 is weak.

After the step using the first plasma 41, the channel layer CX and the first insulating layer I1 are annealed (step S30). Hydrogen is liberated from the first insulating layer I1 through the annealing treatment, and a part of the liberated hydrogen reduces the oxide semiconductor contained in the channel layer CX, and the other part thereof escapes without being reduced. As the diameters of the holes HX increase, hydrogen is more likely to escape through the holes HX, and therefore, the oxide semiconductor in the vicinity of the holes HX is not significantly reduced. Specifically, due to the difference in diameters between the first hole H1 and the second hole H2, the hydrogen liberated from the first portion P1 toward the first channel layer C1 side is more likely to escape than the hydrogen liberated from the second portion P2 toward the second channel layer C2 side. Therefore, the oxide semiconductor contained in the second channel layer C2 is reduced more than the oxide semiconductor contained in the first channel layer C1.

Subsequently, a conductive layer 13 to be the material of gate electrodes GX of the transistors is formed (step S40), and a patterned template layer 51 is formed on the conductive layer 13 (step S42). Then, the conductive layer 13 is etched with a second plasma 42 along the template layers 51 to form the gate electrodes GX of the transistors from the conductive layer 13 (step S44), and the template layers 51 are removed. The gate electrodes GX include a gate electrode G1 and a gate electrode G2. In step S44, as the intensity of the second plasma 42 becomes stronger, the gate length becomes shorter. Specifically, the gate length L1 of the first transistor T1 formed in the region where the intensity of the second plasma 42 is strong is shorter than the gate length L2 of the second transistor T2 formed in the region where the intensity of the second plasma 42 is weak.

According to this manufacturing method, as a result of the effects of the gate lengths and the degree of reduction of the oxide semiconductors on the threshold values of the transistors (at least partially) canceling out, the difference between the threshold values of the transistors in design and the actual threshold values of the transistors can be reduced. In addition, the difference in threshold values between the first transistor T1 formed in the region where the intensity of plasma is strong and the second transistor T2 formed in the region where the intensity of plasma is weak can be reduced.

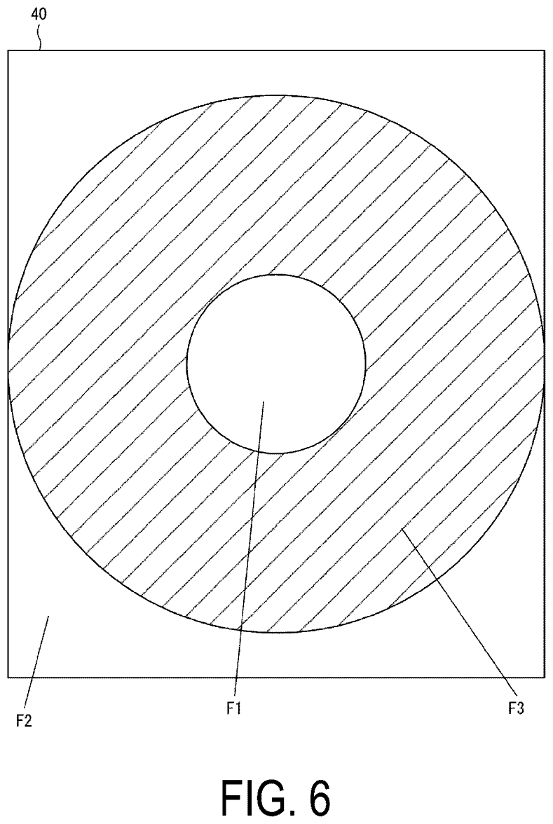

FIG. 6 is a plan view illustrating an example of an intensity distribution of plasma illustrated in FIG. 5. As illustrated in FIG. 6, the first and second plasmas 41 and 42 may each have a spatially non-uniform intensity distribution. Typically, in a chamber 40 in which plasma is generated, the plasma is weak at a center region F1 and a peripheral region F2, and the plasma is strong at an intermediate region F3 therebetween. The shape of the intermediate region F3 corresponds to the shape of the plasma generating electrodes and is usually annular. It is advantageous for the intensity distributions of the first and second plasmas 41 and 42 to be substantially the same. Specifically, it is advantageous for the first and second plasmas 41 and 42 to be strong in the region where the first transistor T1 is formed and the first and second plasmas 41 and 42 to be weak in the region where the second transistor T2 is formed. The intensity distributions may be measured, or the intensity distributions may be estimated based on the configuration of the plasma generator. When the shapes and arrangements of the plasma generating electrodes are the same, it can be determined that the intensity distributions of the first and second plasmas 41 and 42 are the same. Furthermore, the first and second plasmas 41 and 42 may be generated by the same device.

### Second Embodiment

Another embodiment of the disclosure will be described below. Further, members having the same functions as those of the members described in the above-described embodiment will be denoted by the same reference numerals and signs, and a description thereof will not be repeated for convenience of description.

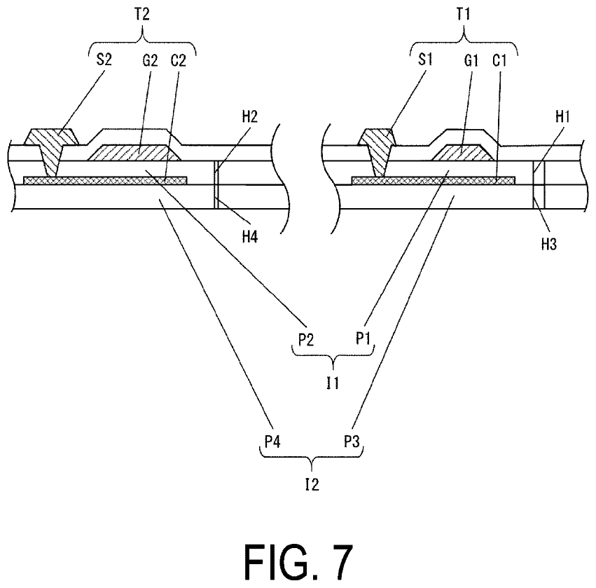

FIG. 7 is a cross-sectional view illustrating a configuration example of a self-luminous display device according to an embodiment of the disclosure. The self-luminous display device 1 according to the disclosure includes a second insulating layer 12 having a third portion P3 in contact with the lower face of a first channel layer C1 and a fourth portion P4 in contact with the lower face of a second channel layer C2 as illustrated in FIG. 7. The density of hydrogen contained in the fourth portion P4 is higher than the density of hydrogen contained in the third portion P3. Furthermore, the diameter of a fourth hole H4 penetrating the vicinity of the fourth portion P4 is smaller than the diameter of a third hole H3 penetrating the vicinity of the third portion P3. The third hole H3 is a through-hole for dehydrogenation of the third portion P3, and the fourth hole H4 is a through-hole for dehydrogenation of the fourth portion P4. The diameter of the fourth hole H4 may be 0, in other words, there may be no dehydrogenation hole in the vicinity of the fourth portion P4. The second insulating layer 12 may be an inorganic insulating layer, and may contain, for example, silicon nitride (SiN), silicon oxide (SiO), or silicon oxynitride (SiNO). The third hole H3 may or may not overlap the first hole H1 in a plan view. The fourth hole H4 may or may not overlap the second hole H2 in a plan view.

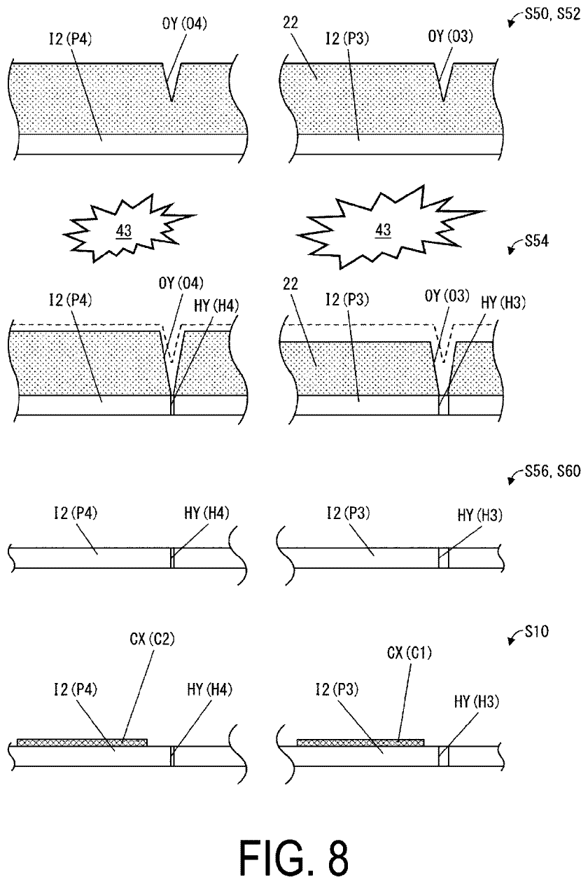

FIG. 8 illustrates cross-sectional views of an example of a method for manufacturing a self-luminous display device according to an embodiment of the disclosure. The second insulating layer 12 that will be in contact with the channel layer CX on the side opposite to the first insulating layer Il is formed as illustrated in FIG. 8 (step S50). In the example illustrated in FIG. 8, the channel layer CX is to be formed on the second insulating layer, and the first insulating layer Il is to be formed on the channel layer CX. The second insulating layer 12 also contains hydrogen at the time of formation. Subsequently, a photoresist layer 22 having openings OY is formed on the second insulating layer 12 (step S52). The openings OY include a third opening 03 overlapping with the formation-planned position of the third hole H3 and a fourth opening O4 overlapping with the formation-planned position of the fourth hole H4. Ideally, the depth and diameter of the fourth opening O4 are identical to the depth and diameter of the third opening O3. It is advantageous for the openings OY not to penetrate.

Then, the photoresist layer 22 and the second insulating layer 12 are etched with a third plasma 43 to form holes HY penetrating the second insulating layer 12 (step S54), and the photoresist layer 22 is removed (step S56). In other words, the photoresist layer 22 is etched with the third plasma 43 so that the openings OY penetrate the photoresist layer 22, and the second insulating layer 12 is etched with the third plasma to form the holes HY. The openings OY overlap the holes HY in a plan view. The holes HY penetrating the second insulating layer 12 include the third hole H3 and the fourth hole H4. The diameter of the third hole H3 formed in the region where the intensity of the third plasma 43 is strong is larger than the diameter of the fourth hole H4 formed in the region where the intensity of the third plasma 43 is weak. The diameter of the fourth hole H4 may be 0.

The third plasma 43 may have a spatially non-uniform intensity distribution. It is advantageous for the intensity distribution of the third plasma 43 to be the same as the intensity distributions of the first and second plasmas 41 and 42. Furthermore, the first to third plasmas 41 to 43 may be generated by the same device.

After the step using the third plasma 43, the channel layer CX and the second insulating layer 12 are annealed (step S60). Hydrogen is liberated from the second insulating layer 12 through the annealing treatment, and a part of the liberated hydrogen reduces the oxide semiconductor contained in the channel layer CX. Then, step S10 and the subsequent steps are performed in order. The annealing treatment in step S60 and step S30 may be performed in the same step. In other words, the channel layer CX, the first insulating layer I1, and the second insulating layer 12 may be annealed after the step using the first plasma 41 and after the step using the third plasma 43.

### Third Embodiment

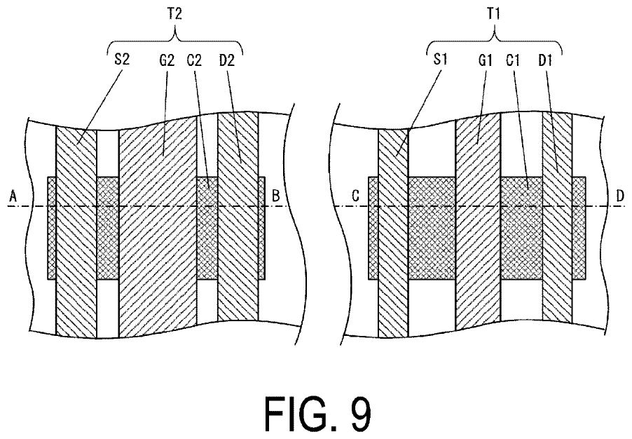

FIG. 9 is a transparent plan view illustrating a configuration example of a self-luminous display device according to an embodiment of the disclosure. The cross-section ABCD of FIG. 9 is the same as that of FIG. 3. In the self-luminous display device 1 according to the disclosure, no dehydrogenation holes are provided in the vicinity of a first channel layer C1 and a second channel layer C2 as illustrated in FIG. 9, and a first insulating layer I1 is doped with oxygen. The self-luminous display device 1 includes the first insulating layer I1 having the first portion P1 in contact with the upper face of the first channel layer C1 and the second portion P2 in contact with the upper face of the second channel layer C2 as illustrated in FIG. 3, and the density of oxygen contained in the second portion P2 is lower than the density of oxygen contained in the first portion P1.

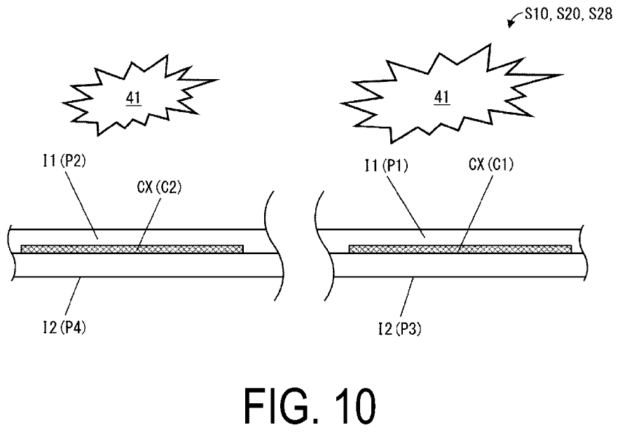

FIG. 10 is a cross-sectional view illustrating an example of a method for manufacturing a self-luminous display device according to an embodiment of the disclosure. Steps S10 and S20 are performed in order, and then, oxygen is introduced into the first insulating layer I1 by using the first plasma 41 with the entire upper face of the first insulating layer Il exposed as illustrated in FIG. 10 (step S28). This can be realized by using oxygen in the first plasma 41, which is so-called “oxygen plasma treatment”. In step S28, as the intensity of the first plasma 41 becomes stronger, the amount of oxygen introduced is greater. To be specific, a larger amount of oxygen is introduced into the first portion P1 positioned in the region where the intensity of the first plasma 41 is strong than into the second portion P2 positioned in the region where the intensity of the first plasma 41 is weak.

Then, step S30 is performed. Oxygen is liberated from the first insulating layer I1 in the annealing treatment, which oxidizes the oxide semiconductor included in the channel layer CX. As the amount of oxygen contained in the first insulating layer I1 increases, the amount of oxygen liberated also increases, and thus the oxide semiconductor is further oxidized. Specifically, due to the difference in the amount of oxygen in the first portion P1 and the second portion P2, the oxide semiconductor included in the first channel layer C1 is oxidized more than the oxide semiconductor included in the second channel layer C2. Additionally or alternatively, oxygen reacts with hydrogen, and more oxygen results in less reduction of the oxide semiconductor by hydrogen.

Subsequently, steps S40, S42, and S44 are performed to remove the template layer 51.

According to this manufacturing method, as a result of the effects of the gate lengths and the degree of reduction of the oxide semiconductors on the threshold values of the transistors (at least partially) canceling out, the difference between the threshold values of the transistors in design and the actual threshold values of the transistors can be reduced. In addition, the difference in threshold values between the first transistor T1 formed in the region where the intensity of plasma is strong and the second transistor T2 formed in the region where the intensity of plasma is weak can be reduced.

### Fourth Embodiment

Referring again to FIGS. 9 and 3, in the self-luminous display device 1 according to the disclosure, the second insulating layer 12 may be doped with oxygen. The self-luminous display device 1 includes the second insulating layer 12 having the third portion P3 in contact with the upper face of the first channel layer C1 and the fourth portion P4 in contact with the upper face of the second channel layer C2, and the density of oxygen contained in the fourth portion P4 is lower than the density of oxygen contained in the third portion P3.

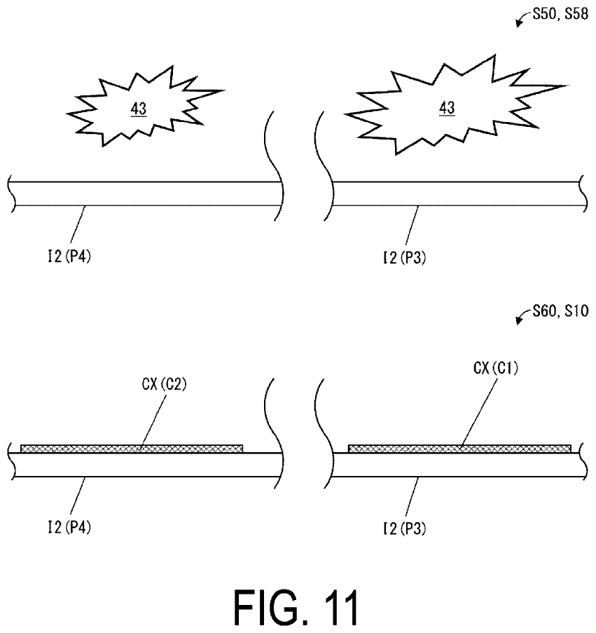

FIG. 11 illustrates cross-sectional views of an example of a method for manufacturing the self-luminous display device according to an embodiment of the disclosure. The second insulating layer 12 that will be in contact with the channel layer CX on the side opposite to the first insulating layer Il is formed as illustrated in FIG. 11 (step S50). In the example illustrated in FIG. 11, the channel layer CX is to be formed on the second insulating layer, and the first insulating layer I1 is to be formed on the channel layer CX. Subsequently, oxygen is introduced into the second insulating layer 12 by using the third plasma 43 with the entire upper face of the second insulating layer 12 exposed (step S58). This can be realized by using oxygen in the third plasma 43. A larger amount of oxygen is introduced into the third portion P3 positioned in the region where the intensity of the third plasma 43 is strong than into the fourth portion P4 positioned in the region where the intensity of the third plasma 43 is weak.

After the step using the third plasma 43, the channel layer CX and the second insulating layer 12 are annealed (step S60). Oxygen is liberated from the second insulating layer 12 in the annealing treatment, which oxidizes the oxide semiconductor included in the channel layer CX. Due to the difference in the amount of oxygen in the third portion P3 and the fourth portion P4, the oxide semiconductor included in the first channel layer C1 is oxidized more than the oxide semiconductor included in the second channel layer C2. Additionally or alternatively, oxygen reacts with hydrogen, and more oxygen results in less reduction of the oxide semiconductor by hydrogen. Then, step S10 and the subsequent steps are performed in order. The annealing treatment in step S60 and step S30 may be performed in the same step.

The disclosure is not limited to the embodiments described above, various modifications may be made within the scope of the claims, and embodiments obtained by appropriately combining technical approaches disclosed in the different embodiments also fall within the technical scope of the disclosure. Furthermore, novel technical features can be formed by combining the technical approaches disclosed in the embodiments.

For example, a dehydrogenation hole may be formed only in the insulating layer in contact with the lower face of the channel layer. For example, only the insulating layer in contact with the lower face of the channel layer may be doped with oxygen. For example, the dehydrogenation hole may be formed in the insulating layer in contact with one face of the channel layer, and the insulating layer in contact with the other face may be doped with oxygen.

1. A self-luminous display device comprising:
a first pixel circuit including a first transistor including a first channel layer including an oxide semiconductor; and
a second pixel circuit with the same circuit configuration as the first pixel circuit, the second pixel circuit including a second transistor corresponding to the first transistor, the second transistor including a second channel layer including an oxide semiconductor,
wherein a gate length of the second transistor is longer than a gate length of the first transistor, and
the oxide semiconductor included in the second channel layer is more reduced than the oxide semiconductor included in the first channel layer.

2. The self-luminous display device according to claim 1,
wherein each of the first transistor and the second transistor is a thin film transistor.

3. The self-luminous display device according to claim 1,
wherein the oxide semiconductor included in the first channel layer and the oxide semiconductor included in the second channel layer are made of the same material.

4. The self-luminous display device according to claim 1,
wherein a gate electrode of the first transistor and a gate electrode of the second transistor are formed in the same layer, and
the first channel layer and the second channel layer are formed in the same layer.

5. The self-luminous display device according to claim 1, comprising:
a first insulating layer including a first portion in contact with an upper face of the first channel layer and a second portion in contact with an upper face of the second channel layer,
wherein a density of hydrogen contained in the second portion is higher than a density of hydrogen contained in the first portion.

6. The self-luminous display device according to claim 1, comprising:
a first insulating layer including a first portion in contact with an upper face of the first channel layer and a second portion in contact with an upper face of the second channel layer,
wherein a diameter of a second hole penetrating a vicinity of the second portion is smaller than a diameter of a first hole penetrating a vicinity of the first portion.

7. The self-luminous display device according to claim 1, comprising:
a first insulating layer including a first portion in contact with an upper face of the first channel layer and a second portion in contact with an upper face of the second channel layer,
wherein a density of oxygen contained in the second portion is lower than a density of oxygen contained in the first portion.

8. The self-luminous display device according to claim 1, comprising:
a second insulating layer including a third portion in contact with a lower face of the first channel layer and a fourth portion in contact with a lower face of the second channel layer,
wherein a density of hydrogen contained in the fourth portion is higher than a density of hydrogen contained in the third portion.

9. The self-luminous display device according to claim 1, comprising:
a second insulating layer including a third portion in contact with a lower face of the first channel layer and a fourth portion in contact with a lower face of the second channel layer,
wherein a diameter of a fourth hole penetrating a vicinity of the fourth portion is smaller than a diameter of a third hole penetrating a vicinity of the third portion.

10. The self-luminous display device according to claim 1, comprising:
a second insulating layer including a third portion in contact with a lower face of the first channel layer and a fourth portion in contact with a lower face of the second channel layer,
wherein a density of oxygen contained in the third portion is lower than a density of oxygen contained in the fourth portion.

11. A method for manufacturing a self-luminous display device comprising:
forming a channel layer including an oxide semiconductor of a transistor;
forming a first insulating layer in contact with the channel layer;
etching the first insulating layer or introducing oxygen into the first insulating layer by using a first plasma to form a hole penetrating the first insulating layer;
annealing the channel layer and the first insulating layer after using the first plasma;
forming a conductive layer serving as a material of a gate electrode of the transistor; and
etching the conductive layer with a second plasma to form the gate electrode of the transistor from the conductive layer.

12. The method for manufacturing a self-luminous display device according to claim 11,
wherein each of the first and second plasmas has a spatially non-uniform intensity distribution.

13. The method for manufacturing a self-luminous display device according to claim 11,
wherein the first and second plasmas have the same intensity distribution.

14. The method for manufacturing a self-luminous display device according to claim 11,
wherein the first and second plasmas are generated by the same device.

15. The method for manufacturing a self-luminous display device according to claim 11, further comprising:
forming a photoresist layer with an opening on the first insulating layer, the opening not penetrating,
wherein the photoresist layer and the first insulating layer are etched with the first plasma.

16. The method for manufacturing a self-luminous display device according to claim 15,
wherein the photoresist layer is etched with the first plasma so that the opening penetrates the photoresist layer, and
the opening overlaps the hole in a plan view.

17. The method for manufacturing a self-luminous display device according to claim 11,
wherein oxygen is introduced into the first insulating layer by using the first plasma with an entire upper face of the first insulating layer exposed.

18. The method for manufacturing a self-luminous display device according to claim 17,
wherein oxygen is used in the first plasma.

19. The method for manufacturing a self-luminous display device according to claim 11,
wherein the first insulating layer is formed on the channel layer.

20. The method for manufacturing a self-luminous display device according to claim 11, further comprising:
forming a second insulating layer in contact with the channel layer on the side opposite to the first insulating layer;
etching the second insulating layer or introducing oxygen into the second insulating layer by using a third plasma to form a hole penetrating the second insulating layer; and
annealing the channel layer and the second insulating layer after using the third plasma.
